(19) United States
(12) Patent Application Publication
(10) Pub. No.: US 2018/0222768 A1
(43) Pub. Date: Aug. 9, 2018

(54) FUNCTIONALIZED METAL OXIDE NANOPARTICLES, METHODS OF PREPARATION AND USES THEREOF

(71) Applicant: Universidad de Antioquia, Medellin (CO)

(72) Inventors: Franklin Jaramillo Isaza, Medellin (CO); Rafael Andres Betancur Lopera, Medellin (CO); John Aider Ciro Villegas, Medellin (CO)

(21) Appl. No.: 15/892,383

(22) Filed: Feb. 8, 2018

Related U.S. Application Data
(60) Provisional application No. 62/456,715, filed on Feb. 9, 2017.

(51) Int. Cl. C01G 53/00; H01L 51/42; C01G 23/00; C01G 9/00; C01G 19/00; C01G 51/00; C01G 3/00

(52) U.S. Cl. CPC C01G 53/006; H01L 51/4226; H01L 51/4233; H01L 51/422; H01L 51/442; C01G 9/006; C01G 19/006; C01G 51/006; C01G 3/006; C01G 23/002

(57) ABSTRACT

Functionalized metal oxides nanoparticles comprising at least one alkali metal ion and nitrate ions are disclosed herein. In addition, methods for obtaining functionalized nanoparticles are disclosed. Likewise, uses of the disclosed nanoparticles in the obtaining of colloidal inks and optoelectronic films for electronic devices, for example solar cells, are disclosed. The nanoparticles taught herein are useful in the manufacture of; inter alia, electronic, optoelectronic and photovoltaic devices.

### FIELD OF THE INVENTION

The present invention refers to functionalized metal oxides nanoparticles, methods of preparation and using the same. The subject matter of this invention may be employed, among others, in electronics, optoelectronics, and photovoltaic devices.

### BACKGROUND

In the last decades, manufacturing of functionalized nanoparticles has been increasing in order to improve certain physical and compatibility properties. For instance, document U.S. Pat. No. 8,512,417 B2 discloses the preparation of metal nanoparticles coupled to linker molecules to form a nanoparticle-linker structure, which may be further bound to various types of substrates such as, inter alia, cellulose substrates, some polymers, polyesters, and polyurethanes. The applications of this type of functionalized nanoparticles include, among others, electronic systems, improved filtration systems, optical, magnetic or catalytic systems, packaging materials, and biosensors.

On the other hand, one of the most important applications of nanoparticles is electronic devices, which include thin films or surface coatings of nanoparticulate materials. For example, nanoparticle films with semiconducting properties allow developing devices such as solar cells, light-emitting diodes, transistors and photodetectors. For these applications, uniform and compact films of material are required, which industrially are typically obtained by physical and chemical methods requiring high vacuum and high temperature processing.

A low-cost processing alternative is based on wet methods in which the nanoparticulate material is dispersed forming a colloidal ink or dispersion. Currently, there are several nanoparticles of different oxides, having semiconducting properties such as n-type or p-type materials, commercially available. However, it has been proven that the dispersibility of such nanoparticles is low, this fact makes the production of compact and thin films for electronic and optoelectronic devices by wet methods impossible. In some cases, it is possible to disperse the nanoparticles using surfactants, coupling and functionalizing agents, but the subsequent cohesion of the resulting film is very poor and the resistance of the nanoparticles interphases is high, thus affecting the electrical properties such as the conductivity.

It has even been found that the use of commercial nanoparticles of transition metal oxides for obtaining thin films, used to transport electric charges in electronic systems, are highly porous with poor connectivity between particles, which decreases the film electrical quality. One way to solve these issues is to subject the coating to heat treatments by using temperatures above 400° C., which might deteriorate the rest of the films and therefore affecting the scalability of the device.

### BRIEF DESCRIPTION

The present invention responds to the needs in the state of the art, by providing conductive metal oxide nanoparticles, which may be homogeneously dispersed forming inks, which allow for production of homogeneous semiconducting films of high degree of uniformity.

In this regard, the present invention provides functionalized semiconducting metal oxide nanoparticles, manufacturing methods and uses thereof. Nanoparticles of the present invention are useful in the manufacture of different electronic and optoelectronic devices such as solar cells.

Functionalized metal oxide nanoparticles disclosed herein present the general structure (Z⁺/NOhd 3⁻)-M_{y}Oₓ, wherein Z⁺ is an alkaline metal ion, M is a metal, y y x are the corresponding subscripts. This metal oxide nanoparticles functionalization improves their physical properties, in particular, providing an increase in the stability of the dispersions of such nanoparticles in different polar solvents and increasing the interconnectivity between particles allowing to get high quality optoelectronic grade films.

Developed functionalized nanoparticles are obtained by a binary functionalization of the initial metal oxide nanoparticles in the presence of nitrate and alkaline metal ions. It has been shown that this functionalization does not interfere with the optical nor electronic performance of the materials.

Furthermore, the functionalization carried out here, allows stabilize colloidal dispersions of the semiconducting metal oxide, and achieving formation of oxide films of optoelectronic quality by a wet process upon improving the interconnectivity between nanoparticles.

An embodiment disclosed herein, shows methods for obtaining functionalized nanoparticles. A first method consisting of the treatment of a nitrate solution of metal M with a base comprising Z⁺, the hydroxide precipitation, its drying and calcination. Another method disclosed herein begins with commercial metal oxide particles and a treatment with a base and a nitrate comprising the alkaline metal ion Z⁺.

In another embodiment, the present invention relates to the use of the functionalized nanoparticles developed herein for preparing a stable colloidal ink without any addition of surfactant, viscous medium, dispersant or any other similar approach to get a stable dispersion. In another embodiment, the use of the disclosed nanoparticles in obtaining optoelectronic films by wet processing and the subsequent obtaining of solar cells is disclosed.

### BRIEF DESCRIPTION OF THE DRAWINGS

FIG. 1 is a general representation of functionalized metal oxide nanoparticles, according to an embodiment described herein.

FIG. 2 corresponds to a TEM image of functionalized nanoparticles developed herein.

FIG. 3 is an x-ray dispersive energy spectrum of functionalized nanoparticles, according to an embodiment.

FIG. 4 corresponds to the thermal gravimetric analysis of functionalized according to an embodiment.

FIG. 5 is an atomic force microscopy image of nickel oxide films obtained according to one embodiment.

FIG. 6 shows an atomic force microscopy image of an optoelectronic grade film obtained from functionalized nanoparticles compared to that obtained from commercial metal oxides.

FIG. 7 corresponds to the analysis of carrier density and hole mobility of a nickel oxide film according to the present invention.

FIG. 8 shows the determination of the solar cells efficiency obtained according to an embodiment disclosed herein. FIG. 8 (a) corresponds to the characterization of a solar cell having the structure glass/ITO(Na⁺/NO₃⁻)—NiOₓ/CH₃NH₃PbI₃/PCBM/Ag. FIG. 8 (b) is the characterization of a solar cell of the structure glass/ITO/(Na+/NO₃—)—TiO₂—NP/CH₃NH₃PbI₃/Spiro-MeOTAD/Ag.

### DETAILED DESCRIPTION OF THE PREFERRED EMBODIMENTS

The present invention will be described in detail below relative to the following embodiments. It should be noted that the following detailed description of the preferred embodiments of the present invention only serves the purpose of illustrating it and, therefore, does not intend to be exhaustive or to be limiting exclusively to the precise forms discussed herein.

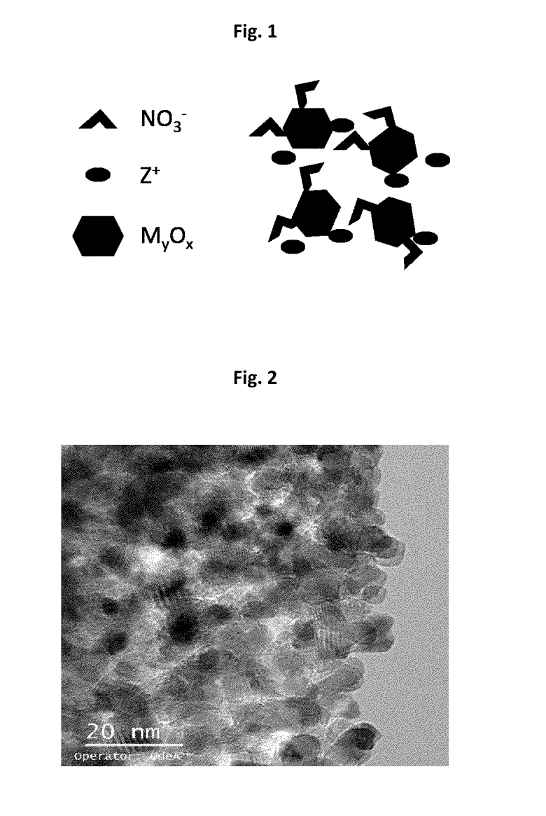

As shown in FIG. 1, an embodiment described herein is related to functionalized nanoparticles of the formula: (Z⁺/NO₃⁻)-M_{y}Oₓ, which may be used in electronic and optoelectronic devices. According to this embodiment, the metal oxide particle is surrounded by the Z⁺ and NO₃⁻ ions, functionalizing it and changing its properties.

According to one embodiment, Z⁺ corresponds to an alkali metal ion and M_{y}Oₓ corresponds to metal oxide nanoparticles, where M is a metal, y and x are the particular subscripts of the oxide.

In one embodiment, the functionalized nanoparticles disclosed herein Z⁺ is an alkaline metal ion selected from the group consisting of Li⁺, Na⁺, Z⁺, Rb⁺, Cs⁺ or Fr⁺. In a preferred embodiment, the alkaline metal ion corresponds to Na⁺.

On the other hand, in accordance to one embodiment, M corresponds to a transition metal. Preferably, M is selected from the group consisting of, inter alia, Ni, Zn, Ti, Sn, Co, Cu. In one embodiment, M_{y}Oₓ is selected from the group consisting of: NiO, ZnO, TiO₂, SnO₂, Co₃O₄ and CuO.

In one of the embodiments of the functionalized nanoparticles disclosed herein M_{y}Oₓ corresponds to nickel oxide (NiOₓ). In another embodiment M_{y}Oₓ corresponds to TiO₂.

FIG. 2 shows the transmission electron microscopy (TEM) analysis of functionalized nanoparticles according to one embodiment. From this analysis, ranges of particle size between 1 nm and 50 nm were achieved. Preferably, the nanoparticles of this embodiment present an average diameter below 10 nm.

In one embodiment, the nanoparticles developed herein comprise atomic percentage of Z⁺ between 0.1% and 10%, and NO₃⁻ between 0.1% and 10% by weight. In another embodiment, the functionalized nanoparticles comprise atomic percentage of Z⁺ between 1% and 5%, and NO₃⁻ between 6% and 8% by weight.

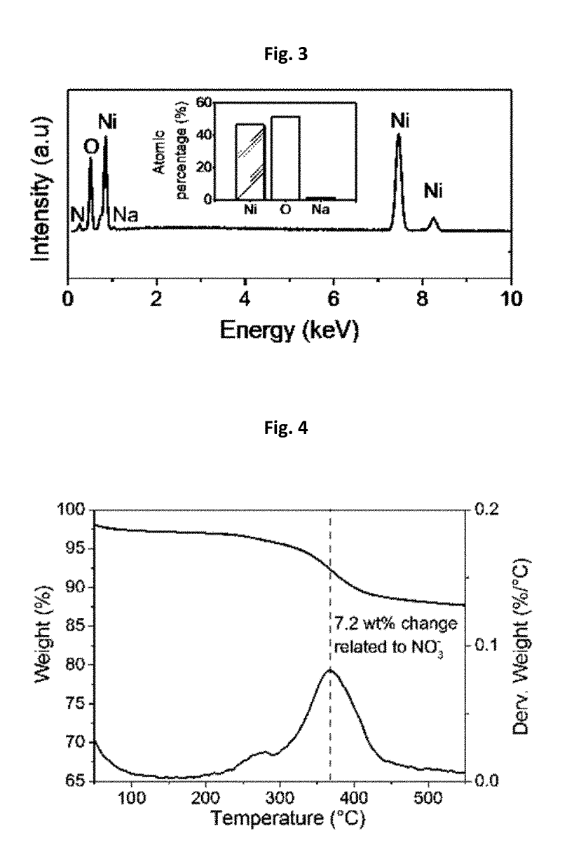

FIG. 3 shows the analysis by means of X-ray energy dispersion of an embodiment of the nanoparticles disclosed herein. In this embodiment nanoparticles comprises Z⁺ 1.83% atomic percentage.

On the other hand, FIG. 4 shows the thermal gravimetric analysis of functionalized nanoparticles according to one embodiment, which comprise NO₃⁻ 7.2% by weight.

According to another embodiment, methods for preparing the functionalized nanoparticles described above are disclosed herein. In one embodiment, a first method comprises the steps of: providing a solution of a nitrate of a transition metal; precipitating the transition metal hydroxide by adding a base containing an alkali metal ion, Z⁺; separating the hydroxide and drying it at a first temperature; and annealing the dry hydroxide to a second temperature. Preferably, in this method, the base/nitrate molar ratio is between 1:1 to 2:1.

On the other hand, according to this embodiment, drying is done under vacuum at a first temperature preferably between 60° C. and 100° C., more preferably 80° C., and the calcination process is done at a temperature between 130° C. and 370° C.

In another embodiment, a second method for preparing the functionalized nanoparticles disclosed herein consists of providing commercial metal oxide nanoparticles; mixing the nanoparticles in a polar solvent; adding a nitrate and a base containing the alkaline metal ion Z⁺; separating the product obtained.

In one embodiment, the dispersion of metal oxide nanoparticles is between 10 mg/mL and 60 mg/mL, and Z⁺ between 0.1% and 10% in atomic percentage and NO₃ between 0.1% and 10% by weight is added.

In another embodiment, the use of the functionalized nanoparticles described herein to reveal stable colloidal inks is disclosed. According to this embodiment, functionalized nanoparticles in powder form are provided, and a polar solvent is added until a stable suspension is obtained. In preferred embodiments, polar solvent in which the suspension is made is selected from the group consisting of protic and aprotic polar solvents, for example, water, alcohols and acids.

In this embodiment, the nanoparticles of the invention are used to obtain colloidal inks, which comprise between 5 mg/mL and 50 mg/mL nanoparticles.

Another embodiment described herein relates to the use of the functionalized nanoparticles developed here for the formation of optoelectronic grade films. According to this embodiment, functionalized nanoparticles are suspended for forming a colloidal ink, and subsequently, a film is grown on a rigid or flexible substrate by means of a substrate coating method.

In this embodiment, the optoelectronic grade film is part of solar cells, diodes, transistors, electrochromic devices, light emitting diodes or batteries.

Preferably, the substrate is a transparent electrode. According to a preferred embodiment of the invention, the transparent electrode is a transparent conductive oxide, more preferably, the transparent conductive oxide is selected from indium tin oxide (ITO), fluorine doped tin oxide (FTO) and aluminum doped zinc oxide. According to this embodiment, the substrate coating method is selected from spin coating, doctor blade, slot-die and the alike methods, obtaining film thicknesses between 10 nm and 50 nm.

FIG. 5 shows an atomic force microscopy analysis of an optoelectronic grade film obtained from the functionalized nanoparticles disclosed herein. Such figure shows how the films obtained by the use disclosed herein have a thickness of around 20 nm. Advantageously, the optoelectronic grade films obtained in the use disclosed herein are compact and of low roughness.

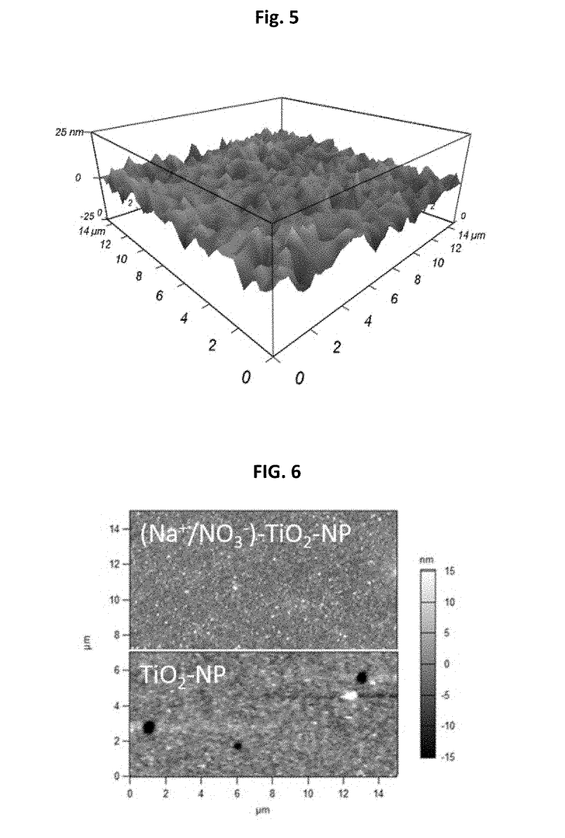

FIG. 6 discloses an atomic force microscopy image of an optoelectronic grade film obtained from functionalized nanoparticles of the invention ((Na+/NO3-)-TiO2-NP) compared to that obtained from commercial metal oxides (TiO2-NP). It is apparent from this figure that the optoelectronic grade films obtained according to the use disclosed herein have an improved morphology, thus reducing the pinholes significantly.

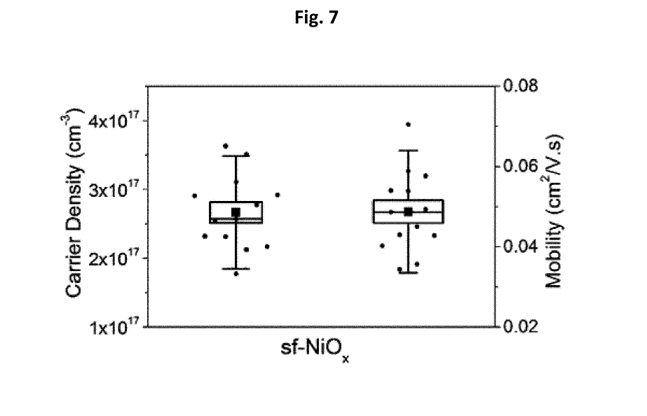

Such optoelectronic grade films obtained by the use of the invention, further have a carrier density and hole mobility similar to that of films obtained through physical methods from commercial metal oxide nanoparticles (FIG. 7).

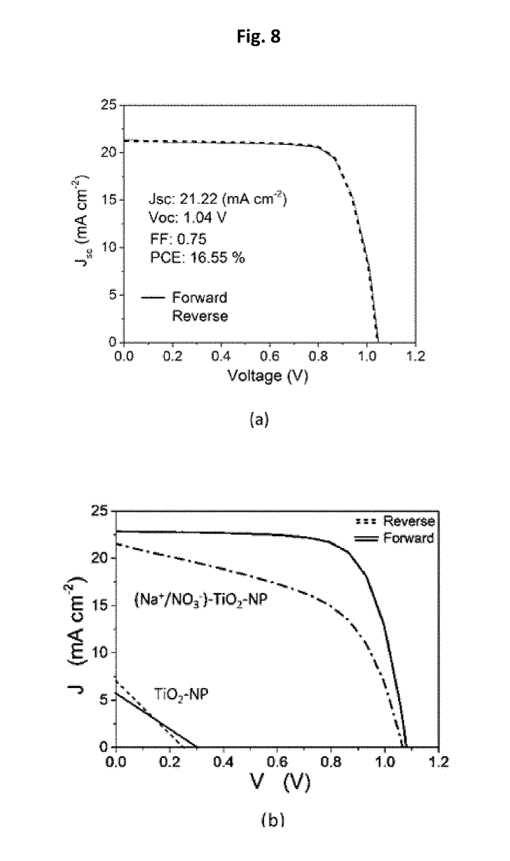

In another embodiment, the use of functionalized nanoparticles for obtaining a solar cell, which comprises a thin optoelectronic grade film of the functionalized nanoparticles of the invention, is disclosed. According to this embodiment, high-efficiency solar cells are obtained. FIGS. 8 (a) and (b) depict the characterization of solar cells obtained according to this embodiment, which include an optoelectronic grade film of the functionalized nanoparticles disclosed herein. This figure shows how the cell efficiency is greater than 16%.

### EXAMPLES

### Example 1 Obtaining of Self-Functionalized Nickel Oxide Nanoparticles, (Na⁺/NO₃⁻)—NiOₓ)

Ni(NO₃)₂.6H₂O was dissolved in water. NaOH was added in such way that molar ratio NaOH:Ni(NO₃)₂.6H₂O would be close to 1.8 reaching a pH 10. Using a centrifuge, the product was precipitated, which was washed with deionized water until the supernatant reached a neutral pH. Subsequently, the precipitate was dried under vacuum at 80° C. for 12 hours. Material obtained was calcined at 270° C. for 4 hours in order to obtain a dark powder of nickel oxide containing the functionalization with sodium and nitrate. These functionalized nanoparticles (Na⁺/NO₃⁻)—NiOₓ) had average sizes below 10 nm (FIG. 2), sodium 1.83% in atomic percentage (FIG. 3), and a content of nitrate 7.2% by weight (FIG. 4). Subsequently, the suspension of nanoparticles obtained in deionized water was carried out in approximate concentrations of 20 mg/mL, thus achieving a stable dispersion. The same procedure was carried out using potassium and lithium as alkali metal ions, with similar results.

### Example 2 Obtaining an Optoelectronic Grade Film from (Na⁺/NO₃⁻)—NiOₓ)

From a NiO_{X} dispersion obtained according to Example 1, a film of the material was grown upon a transparent electrode (ITO or FTO) by means of a known substrate coating method (for example, spin coating, doctor blade, slot-die, among others). The resulting film was compact, it showed low roughness and a thickness close to 20 nm (FIG. 5). Surprisingly, the electronic characterization of the film obtained herein showed that the carrier density and hole mobility is comparable to that achieved when nickel oxide is grown by physical methods such as sputtering (FIG. 7). Finally, the optoelectronic quality of the film (Na⁺/NO₃⁻)—NiOₓ obtained was demonstrated when used as a hole transport material in a solar perovskite cell of the structure: glass/ITO(Na⁺/NO₃⁻)—NiOₓ/CH₃NH₃PbI₃/PCBM/Ag, reaching an efficiency of 16.5% (FIG. 8 (a)).

### Example 3 Obtaining Functionalized Titanium Oxide Nano Particles (Na⁺/NO₃⁻)—TiO₂—NP) and Optoelectronic Grade Film Formation

Commercial TiO₂ nanoparticles (TiO₂—NP) with a particle size close to 5 nm were dispersed in water at concentrations up to 50 mg/mL. 100 mg of sodium nitrate were added, and the pH of the dispersion was adjusted to 10 by using NaOH. The mixture was vigorously stirred for 10 minutes. Using a centrifuge, the product was precipitated, and washed twice. Finally, the resulting product was re-dispersed in water at concentrations around 20 mg/mL. The (Na⁺/NO₃⁻)—TiO₂—NP final film was grown by a known substrate coating method (for example, spin coating, doctor blade, slot-die, among others) reaching thicknesses less than 50 nm and high uniformity. The (Na⁺/NO₃⁻)—TiO₂—NP) films have a lower number of pinholes compared to (TiO2-NP) films and have a greater interconnection between particles as seen in FIG. 6. As proof of their optoelectronic quality, (Na⁺/NO₃⁻)—TiO₂—NP films were implemented in perovskite solar cells of the structure glass/ITO/(Na⁺/NO₃⁻)—TiO₂—NP/CH₃NH₃PbI₃/Spiro-MeOTAD/Ag, thus achieving efficiencies exceeding 16% (FIG. 8 (b)), while, devices using particles without functionalization (TiO₂—NP) exhibit deficient photovoltaic parameters.

### Example 4 Characterization of Obtained Functionalized Nanoparticles, their Inks and Films

TABLE 1

| | Functionalized nanoparticles | | | | | | | | |
|---|---|---|---|---|---|---|---|---|---|
| | | | Alkaline | | | | Nanoparticles ink | | |
| | Chemical | Alkaline | metal ion | Nitrate ion | | | | Minimum | |
| | Structure | metals | percentage | percentage | | Size | | stability | Films |
| Material | MyOx | Z⁺ | (atomic %) | (% weight) | Form | (nm) | Solvent | (days) | Thickness (nm) |
| Nickel | NiOₓ | Li, Na, K | 1-3% | 2-10% | Spherical | 6 | Water | 40 | 20-100 |
| Oxide | | | | | | | Chlorobenzene | 5 | |
| Zinc oxide | ZnOₓ | K | 1-3% | 2-10% | Spherical | 4 | Chlorobenzene | 5 | 10-100 |
| | | | | | | | Butanol | | |
| | | | | | | | Water | | |
| Titanium | TiOₓ | Na | 1-5% | <10% | Spherical | 5 | Water | 90 | 10-150 |
| oxide | | | | | | | Butanol | 7 | |
| Tin dioxide | SnOₓ | Na | 1-5% | <10% | Spherical | 10 | Isopropanol | 7 | 20-150 |
| | | | | | | | Butanol | | |
| Cobalt | CoOₓ | Na, K | 1-3% | 2-10% | Spherical | 5 | Water | 15 | 10-100 |
| oxide | | | | | | | | | |
| Copper | CoOₓ | Na, K | 1-3% | 2-10% | Spherical | 10 | Butanol | 15 | 20-150 |
| oxide | | | | | | | | | |
| Commercial | NiO | — | — | — | — | 10 | Water | Unstable | Porous films, |
| nickel oxide | | | | | | | Chlorobenzene | | non- |
| | | | | | | | Isopropanol | | interconnected |
| | | | | | | | Butanol | | nanoparticles. |
| Commercial | TiO₂ | — | — | — | — | 5 | Water | Stable | Porous film, |
| titanium | | | | | | | | | non- |
| oxide | | | | | | | | | interconnected |
| | | | | | | | | | nanoparticles. |
| Commercial | ZnO | — | — | — | — | 5 | Water | Unstable | Porous films, |
| zinc oxide | | | | | | | Chlorobenzene | | non- |
| | | | | | | | Isopropanol | | interconnected |
| | | | | | | | Butanol | | nanoparticles. |

Table 1 shows the characterization results of some of the nanoparticles disclosed herein, as well as the inks and films obtained therefrom, in contrast to those obtained with commercial metal oxide nanoparticles.

Functionalized nanoparticles were obtained by means of methods described herein and the nanoparticles characterized by means of Energy-dispersive X-ray spectroscopy (EDS), Raman spectroscopy, Fourier Transform Infrared (FTIR), and thermal gravimetric analysis in order to determine the elements present and the Z⁺ and Nitrates quantity. Particle form and size determination was carried out by means of Transmission electron microscopy (TEM).

The inks were obtained by dispersing functionalized nanoparticles in a concentration of between 20 mg/mL and 25 mg/m L, and to test their stability, they were left at rest, at room temperature, until phase separation occurred.

Films growth was done by means of coating equipment such as Spin coater, Spray coater, Slot-die coater, and Doctor Blade.

Surprisingly, the functionalized nanoparticles disclose herein have particle size comparable to commercial metal oxide nanoparticles, but, they allow obtaining inks with superior stability in polar solvents, even stable for 90 days.

Likewise, the films obtained from the commercial metal oxide nanoparticles are porous with non-interconnected nanoparticles. In contrast, the films formed from the functionalized nanoparticles disclosed herein were homogeneous films with a thickness between 10 nm and 150 nm.

Considering the invention described herein, in the terms previously presented, and for practical purposes in the preferred embodiments, it should be understood that the invention does not need to be exclusively limited to the preferred embodiments. On the contrary, it intends to cover several modifications and similar re-arrangements included within the scope of the claims, which are in accordance with the broadest interpretation of the present description in order to cover all such modifications and similar structures.

1. Functionalized nanoparticles of Formula
(Z⁺/NO₃⁻)-M_{y}Oₓ
wherein:
Z⁺ corresponds to an alkali metal ion and M_{y}Oₓ corresponds to metal oxide nanoparticle, where M is a metal, y and x are the particular subscripts of the oxide.

2. The functionalized nanoparticles according to claim 1, wherein the alkaline metal ion Z⁺is selected from a group consisting of Li⁺, Na⁺, K⁺, Rb⁺, Cs⁺ or Fr⁺.

3. The functionalized nanoparticles according to claim 1, wherein M is transition metal.

4. The functionalized nanoparticles according to claim 1, wherein M_{y}Oₓ is selected from a group consisting of NiO, ZnO, TiO₂, SnO₂, Co₃O₄, CuO.

5. The functionalized nanoparticles according to claim 1, wherein it comprises nitrates between 0.1% and 10% by weight.

6. The functionalized nanoparticles according to claim 1, wherein it comprises Z⁺ between 0.1% and 10% atomic.

7. Functionalized nanoparticles according to claim 1, wherein the average diameter of the mentioned functionalized nanoparticles is below 10 nm.

8. A method for preparing the stable functionalized nanoparticles according to claim 1, comprising:
providing a soluble nitrate solution of a transition metal;
precipitating the hydroxide of the transition metal by means of the addition of one base containing an alkaline metal ion Z⁺,
separating the hydroxide and drying it at a first temperature; and annealing the dry hydroxide to a second temperature.

9. The method of claim 7, wherein the first temperature is between 60° C. and 100° C., and the second temperature is between 130° C. and 370° C.

10. The functionalized nanoparticles according to claim 1, for use in the obtaining of a stable colloidal ink, which comprises a polar solvent.

11. The functionalized nanoparticles of claim 10, wherein the solvent is selected from the group consisting of protic and aprotic polar solvents.

12. The functionalized nanoparticles of claim 10, wherein the concentration of functionalized nanoparticles is between 5 and 50 mg/mL.

13. The functionalized nanoparticles according to claim 1, for its use in the production of an optoelectronic grade film.

14. The functionalized nanoparticles according to claim 13, wherein the film is part of solar cells, diodes, transistors, electrochromic devices, light emitting diodes or batteries.

15. The functionalized nanoparticles according to claim 1, for its use in the obtaining of a solar cell.
